(19) United States
(12) Patent Application Publication
(10) Pub. No.: US 2026/0291440 A1
(43) Pub. Date: Sep. 24, 2026

(54) SINGLE-PHASE DIFFERENTIAL CONVERSION CIRCUIT

(71) Applicant: NTT, Inc, Tokyo (JP)

(72) Inventors: Teruo Jo, Tokyo (JP); Munehiko Nagatani, Tokyo (JP); Tsutomu Takeya, Tokyo (JP); Hiroyuki Takahashi, Tokyo (JP); Hitoshi Wakita, Tokyo (JP)

(21) Appl. No.: 18/712,190

(22) PCT Filed: Nov. 30, 2021
(86) PCT No.: PCT/JP2021/043800

§ 371 Date: Apr. 27, 2026

(51) Int. Cl. H03F 1/02; H03F 3/45

(52) U.S. Cl. CPC H03F 1/0233; H03F 3/45085; H03F 2200/378; H03F 2200/381

(57) ABSTRACT

A single-phase differential conversion circuit of the present invention is provided with a differential amplifier including a positive-phase circuit for processing a positive-phase signal and a negative-phase circuit for processing a negative-phase signal; and a transmission line connected to an output terminal of the positive-phase circuit, wherein the transmission line rotates a phase of the positive-phase signal and reduces an intensity of the positive-phase signal. The other differential amplifier may be connected to a subsequent stage of the differential amplifier.

### CROSS-REFERENCE TO RELATED APPLICATIONS

This application is a national phase entry of PCT Application No. PCT/JP2021/043800, filed on Nov. 30, 2021, which application is hereby incorporated herein by reference.

### TECHNICAL FIELD

The present invention relates to a single-phase differential conversion circuit in which a transmission line is connected to a differential amplifier.

### BACKGROUND

In a high-speed optical communication system, a single-phase differential conversion circuit for a baseband signal is required to have good differential characteristics, that is, to have a small mismatch between a 180-degree phase differences and intensities between differential signals.

As a technology for converting a single-phase baseband signal into a differential baseband signal, a technology using a differential amplifier 71 is disclosed as illustrated in FIG. 10 (Non Patent Literature 1). In this technology, a signal is input to one (positive-phase circuit side) terminal In of the differential amplifier 71, and the other (negative-phase circuit side) terminal is fixed to the common bias (Vb), whereby a differential signal is obtained at the output terminal (OutP, OutN). Hereinafter, the OutP side (In side) is referred to as a positive-phase circuit side, and the OutN side (Vb side) is referred to as a negative-phase circuit side.

### CITATION LIST

### Non Patent Literature

Non Patent Literature 1: Casas, Roberto, Oscar Casas, and Vittorio Ferrari, “Single-ended input to differential output circuits. A comparative analysis”, 2006 IEEE Instrumentation and Measurement Technology Conference Proceedings. IEEE, 2006.

### SUMMARY

### Technical Problem

However, the conventional single-phase differential conversion circuit has a problem that differential characteristics are deteriorated at high frequencies. FIG. 11 is a schematic diagram of a conventional single-phase differential conversion circuit (differential amplifier 71). As illustrated in FIG. 11, as the signal has a high frequency, the impedance of the parasitic capacitance 72 of the transistor decreases. Accordingly, since a phase of the signal on the positive-phase circuit side rotates via the parasitic capacitance 72 and is added to a signal on the negative-phase circuit side, the differential characteristics deteriorate at high frequencies in the conventional single-phase differential conversion circuit.

Specifically, when the signal has a low frequency, the impedance of the parasitic capacitance 72 is high, so that the signal is cut off.

On the other hand, when the signal has a high frequency, the impedance of the parasitic capacitance 72 decreases, and the signal flows into the signal on the negative-phase circuit side (indicated by an arrow 73 In the drawing). This signal rotates in phase during propagation and adds to the negative-phase signal. In addition, the signal intensity on the negative-phase circuit side is also reduced.

As described above, when the signal has a high frequency, the impedance of the parasitic capacitance 72 decreases, and the positive-phase signal affects the negative-phase signal.

FIGS. 12A and 12B illustrate simulation results of differential characteristics in the conventional single-phase differential conversion circuit. As illustrated in FIG. 12A, the mismatch of the 180° phase difference is 22° at 140 GHz. As illustrated in FIG. 12B, the intensity mismatch is 3.5 dB at 140 GHz. As described above, differential characteristics are deteriorated at high frequencies in the conventional single-phase differential conversion circuit.

### Solution to Problem

To address the problems described above, a single-phase differential conversion circuit according to embodiments of the present invention is provided with a differential amplifier including a positive-phase circuit for processing a positive-phase signal and a negative-phase circuit for processing a negative-phase signal; and a transmission line connected to an output terminal of the positive-phase circuit, wherein the transmission line rotates a phase of the positive-phase signal and reduces an intensity of the positive-phase signal.

Further, a single-phase differential conversion circuit according to the present invention is provided with a differential amplifier including a positive-phase circuit for processing a positive-phase signal and a negative-phase circuit for processing a negative-phase signal; and a compensation circuit, wherein the compensation circuit includes, at an output terminal of the positive-phase circuit, a resistor and an inductor connected in series, and a capacitor connected in parallel.

### Advantageous Effects of Embodiments of the Invention

According to embodiments of the present invention, it is possible to provide a single-phase differential conversion circuit having good differential characteristics.

### BRIEF DESCRIPTION OF DRAWINGS

FIG. 1A is a block diagram illustrating a configuration of a single-phase differential conversion circuit according to a first embodiment of the present invention.

FIG. 1B is a circuit diagram illustrating a configuration of the single-phase differential conversion circuit according to the first embodiment of the present invention.

FIG. 2A is a diagram illustrating an effect of the single-phase differential conversion circuit according to the first embodiment of the present invention.

FIG. 2B is a diagram for illustrating the effect of the single-phase differential conversion circuit according to the first embodiment of the present invention.

FIG. 3 is a block diagram illustrating a configuration of a single-phase differential conversion circuit according to a second embodiment of the present invention.

FIG. 4A is a diagram for illustrating an effect of the single-phase differential conversion circuit according to the second embodiment of the present invention.

FIG. 4B is a diagram for illustrating the effect of the single-phase differential conversion circuit according to the second embodiment of the present invention.

FIG. 5 is a block diagram illustrating a configuration of a single-phase differential conversion circuit according to a third embodiment of the present invention.

FIG. 6A is a block diagram illustrating a configuration of a single-phase differential conversion circuit according to a fourth embodiment of the present invention.

FIG. 6B is a block diagram illustrating a configuration of the single-phase differential conversion circuit according to the fourth embodiment of the present invention.

FIG. 7 is a circuit diagram illustrating a configuration of a compensation circuit in a single-phase differential conversion circuit according to a fifth embodiment of the present invention.

FIG. 8 is a circuit diagram illustrating one example of the configuration of the compensation circuit in the single-phase differential conversion circuit according to the fifth embodiment of the present invention.

FIG. 9 is a block diagram illustrating a configuration of a single-phase differential conversion circuit according to a sixth embodiment of the present invention.

FIG. 10 is a block diagram illustrating a configuration of a conventional single-phase differential conversion circuit.

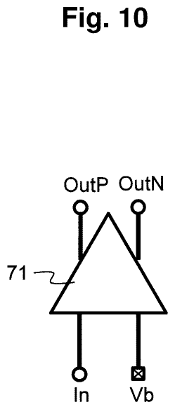

FIG. 11 is a schematic diagram illustrating the conventional single-phase differential conversion circuit.

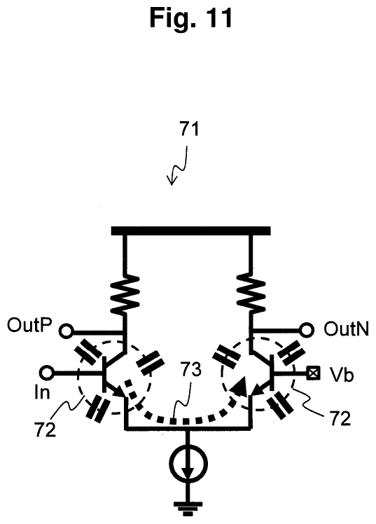

FIG. 12A is a diagram illustrating performance of the conventional single-phase differential conversion circuit.

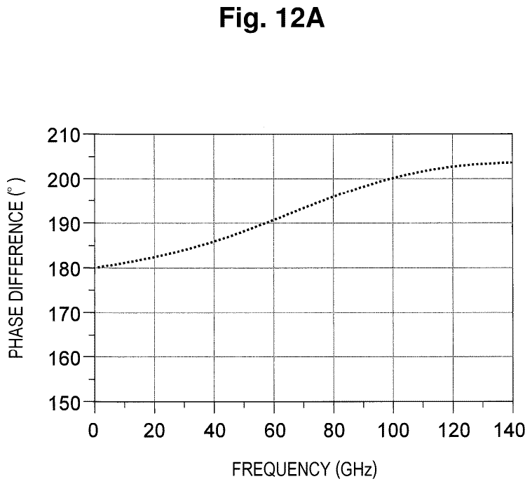

FIG. 12B is a diagram illustrating performance of the conventional single-phase differential conversion circuit.

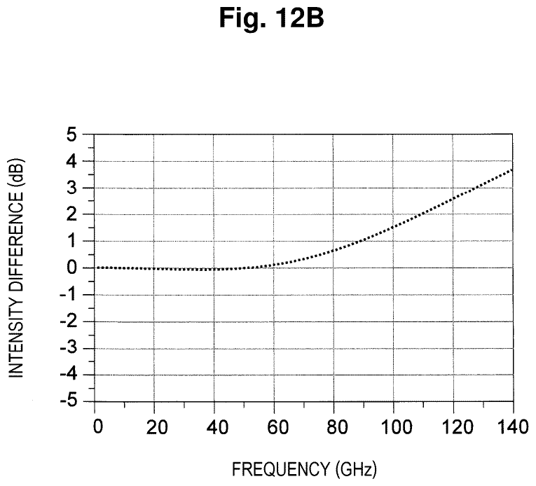

### DETAILED DESCRIPTION OF ILLUSTRATIVE EMBODIMENTS

### First Embodiment

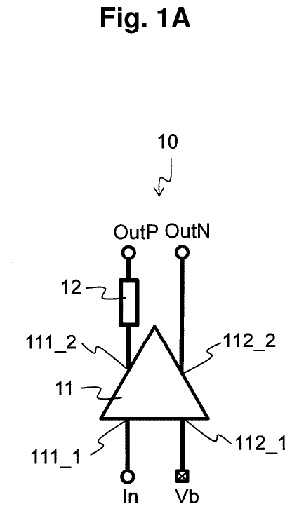

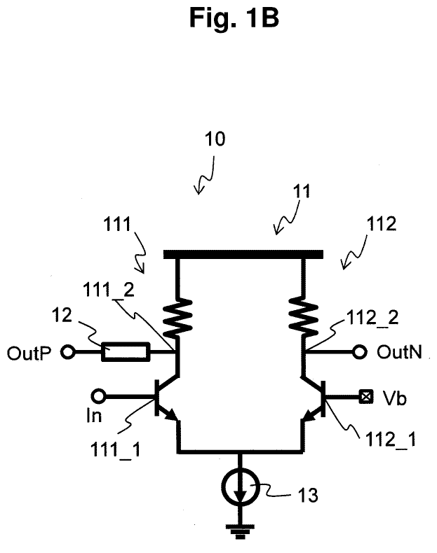

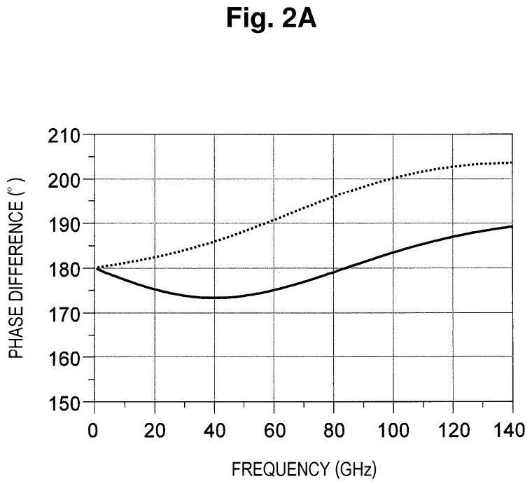

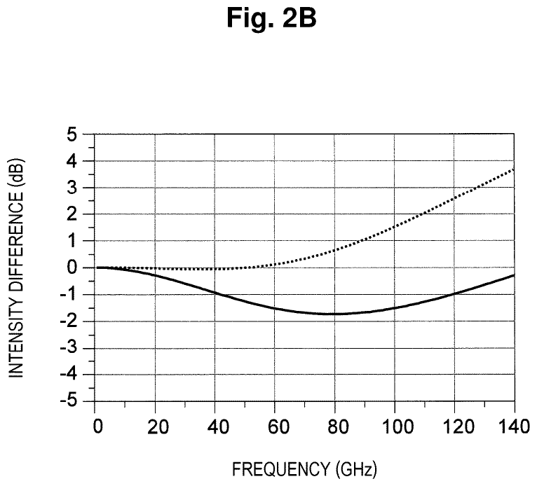

A single-phase differential conversion circuit according to a first embodiment of the present invention will be described with reference to FIGS. 1A to 2B.

### Configuration of Single-Phase Differential Conversion Circuit

As illustrated in FIGS. 1A and 1B, a single-phase differential conversion circuit 10 according to the present embodiment includes a differential amplifier 11 and a transmission line 12. A tail current source 13 may also be provided.

The differential amplifier 11 includes a circuit (hereinafter referred to as a “positive-phase circuit”) 111 that processes a positive-phase signal and a circuit (hereinafter referred to as a “negative-phase circuit”) 112 that processes a negative-phase signal, which is further provided with an input terminal 111_1 and an output terminal 111_2 of the positive-phase circuit 111 and an input terminal 112_1 and an output terminal 112_2 of the negative-phase circuit 112.

In addition, the single-phase differential conversion circuit 10 includes an input terminal In and an output terminal OutP on the positive-phase circuit 111 side, and a terminal Vb and an output terminal OutN connected to a common mode voltage on the negative-phase circuit 112 side.

The transmission line 12 is connected between the output terminal 111_2 of the positive-phase circuit 111 of the differential amplifier 11 and the output terminal OutP on the positive-phase circuit 111 side.

In the single-phase differential conversion circuit 10, since the transmission line is also connected to the wiring (not illustrated) on the negative-phase circuit 112 side, the transmission line 12 connected to the side of the positive-phase circuit 111 only needs to be longer than the transmission line on the negative-phase circuit 112 side.

The transmission line 12 can correct the mismatch of the 180° phase difference by excessively rotating the phase of the output signal on the positive-phase circuit 111 side with respect to the output signal on the negative-phase circuit 112 side. Since the signal intensity on the positive-phase circuit 111 side is reduced in the transmission line 12, it is possible to correct a mismatch in the intensity with respect to the negative-phase circuit 112 side.

### Effect of Single-Phase Differential Conversion Circuit

FIGS. 2A and 2B illustrate simulation results of differential characteristics in the single-phase differential conversion circuit 10 according to the present embodiment (solid line in the drawing). For reference, simulation results of differential characteristics in the conventional single-phase differential conversion circuit are also shown (dotted line in the drawing).

Calculation was performed using “Advanced Design System” (sold by Keysight Technologies, Inc.). In the calculation, the phase and intensity of the input sine wave defined by the frequency component are set, and a phase amount to be rotated in the transmission line 12 is set. The phase amount to be rotated in the transmission line 12 is set to 13 degrees.

In the conventional single-phase differential conversion circuit, the frequency is 0 to 140 GHz, the mismatch of the 180° phase difference is 22°, and the mismatch of the intensity difference is 3.5 dB.

On the other hand, in the single-phase differential conversion circuit 10 according to the present embodiment, the frequency is 0 to 140 GHz, the mismatch of the 180° phase difference is 9°, and the mismatch of the intensity difference is 1.8 dB. As described above, as compared with the conventional single-phase differential conversion circuit, both the mismatch of the phase difference and the mismatch of the intensity difference are reduced and improved.

The ideal phase difference characteristic is that the phase difference is constant at 180 degrees, that is, the mismatch of the 180° phase difference is 0°; however, it is sufficient as long as the mismatch of the 180° phase difference can be reduced within a predetermined range. For example, the angle may be reduced to about 10% or less of 180 degrees.

The mismatch of the 180° phase difference of the differential amplifier 11 is a maximum generally at the highest frequency of the desired band (For example, 140 GHz in FIG. 2). By using the transmission line 12 having a phase rotation amount equivalent to the mismatch amount of the phase difference, it is possible to ameliorate the mismatch of the phase difference to the maximum.

According to the single-phase differential conversion circuit according to the present embodiment, the mismatch of the phase difference and the mismatch of the intensity difference are both made, and good differential characteristics are obtained.

### Second Embodiment

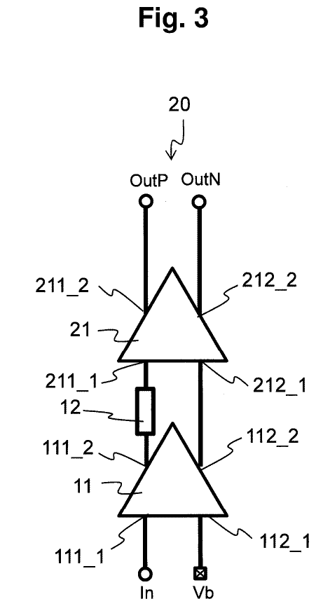

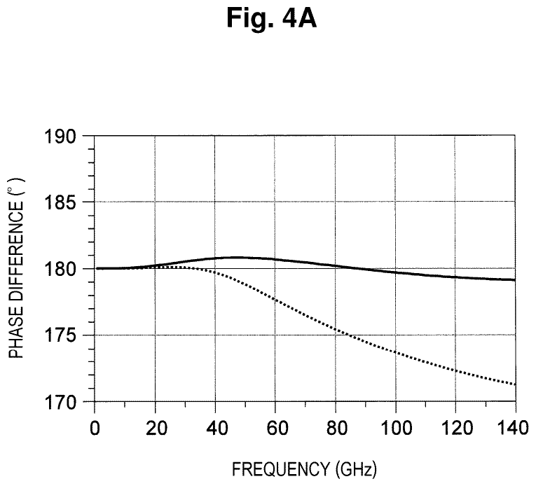

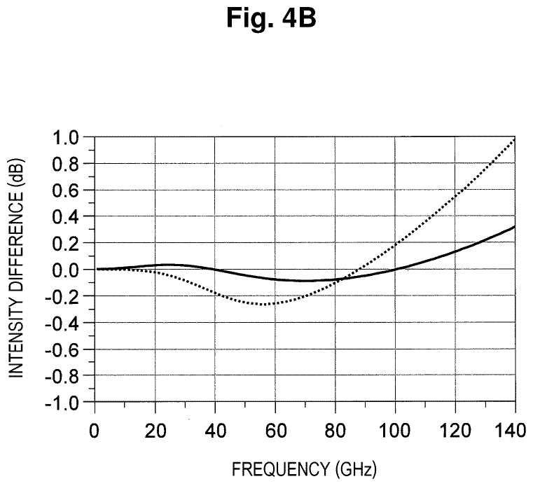

A single-phase differential conversion circuit according to a second embodiment of the present invention will be described with reference to FIGS. 3 to 4B.

### Configuration of Single-Phase Differential Conversion Circuit

As illustrated in FIG. 3, a single-phase differential conversion circuit 20 according to the present embodiment includes two differential amplifiers 11 and 21, and a transmission line 12 connected between an output terminal 111_2 of a positive-phase circuit 111 of the differential amplifier 11 at the preceding stage and an input terminal 211_1 of a positive-phase circuit 211 of the differential amplifier 21 at the subsequent stage among the two differential amplifiers 11 and 21.

In other words, another differential amplifier 21 is connected at the subsequent stage of the single-phase differential conversion circuit 10 according to the first embodiment.

Since the differential amplifier 21 at the subsequent stage can remove the common mode, the differential characteristics of the single-phase differential conversion circuit 20 are improved.

### Effect of Single-Phase Differential Conversion Circuit

FIGS. 4A and 4B illustrate simulation results of differential characteristics in the single-phase differential conversion circuit 20 according to the present embodiment (solid line in the drawing). For reference, simulation results of differential characteristics in a conventional single-phase differential conversion circuit, that is, a single-phase differential conversion circuit including two stages of differential amplifiers 11 and 21 but not having a transmission line is also shown (dotted line in the drawing).

In the conventional single-phase differential conversion circuit, the frequency is 0 to 140 GHz, the mismatch of the 180° phase difference is 9°, and the mismatch of the intensity difference is 1 dB.

On the other hand, in the single-phase differential conversion circuit 20 according to the present embodiment, the frequency is 0 to 140 GHz, the mismatch of the 180° phase difference is 1°, and the mismatch of the intensity difference is 0.3 dB. As described above, as compared with the conventional single-phase differential conversion circuit, both the mismatch of the phase difference and the mismatch of the intensity difference are reduced and improved.

According to the single-phase differential conversion circuit according to the present embodiment, the mismatch of the phase difference and the mismatch of the intensity difference are both made, and good differential characteristics are obtained.

In the present embodiment, the example in which the differential amplifier with two stages is used has been described, but the present invention is not limited thereto. A differential amplifier with three or more stages may be used, whereby the differential characteristics can be further improved.

### Third Embodiment

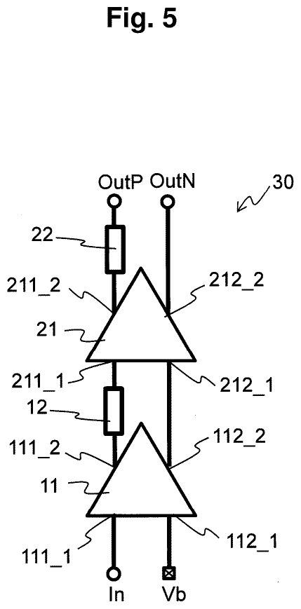

A single-phase differential conversion circuit according to a third embodiment of the present invention will be described with reference to FIG. 5.

As illustrated in FIG. 5, a single-phase differential conversion circuit 30 according to the present embodiment includes two differential amplifiers 11 and 21 and two transmission lines 12 and 22.

Each of the two transmission lines 12 and 22 is connected between an output terminal 111_2 of a positive-phase circuit 111 of the differential amplifier 11 at the preceding stage and an input terminal 211_1 of a positive-phase circuit 211 of the differential amplifier 21 at the subsequent stage, and between an output terminal 211_2 of the positive-phase circuit 211 of the differential amplifier 21 at the subsequent stage and an output terminal OutP on the positive-phase circuit side of the single-phase differential conversion circuit 30, respectively.

Accordingly, the degree of freedom of design parameters of the single-phase differential conversion circuit increases, and the differential characteristics can be further improved.

According to the single-phase differential conversion circuit according to the present embodiment, both the mismatch of the phase difference and the mismatch of the intensity difference are made, the degree of freedom of the design parameters is increased, and further, good differential characteristics are obtained.

### Fourth Embodiment

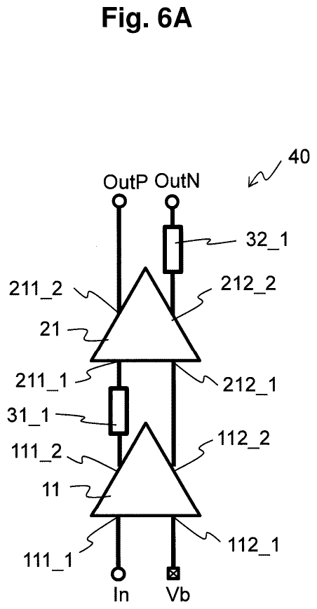

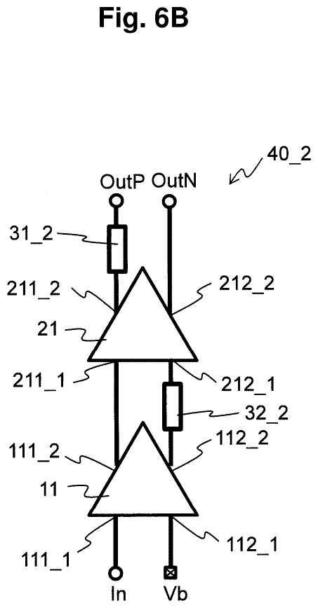

A single-phase differential conversion circuit according to a fourth embodiment of the present invention will be described with reference to FIGS. 6A and 6B.

As illustrated in FIG. 6A, a single-phase differential conversion circuit 40 according to the present embodiment includes two differential amplifiers 11 and 21 and two transmission lines 31_1 and 32_1.

Each of the two transmission lines 31_1 and 32_1 is connected between an output terminal 111_2 of a positive-phase circuit 111 of the differential amplifier 11 at the preceding stage and an input terminal 211_1 of a positive-phase circuit 211 of the differential amplifier 21 at the subsequent stage, and between an output terminal 212_2 of a negative-phase circuit 212 of the differential amplifier 21 at the subsequent stage and an output terminal OutN on the negative-phase circuit side of a single-phase differential conversion circuit 40, respectively.

Moreover, as shown in FIG. 6B, each of the two transmission lines 31_2 and 32_2 may be connected between an output terminal 112_2 of the negative-phase circuit 112 of the differential amplifier 11 at the preceding stage and an input terminal 212_1 of the negative-phase circuit 212 of the differential amplifier 21 at the subsequent stage, and between an output terminal 211_2 of the positive-phase circuit 211 of the differential amplifier 21 at the subsequent stage and an output terminal OutP on the positive-phase circuit side of a single-phase differential conversion circuit 40_2, respectively.

According to the single-phase differential conversion circuit according to the present embodiment, when peaking or ripple occurs in the frequency characteristics of the single-phase differential conversion circuit, the peaking or ripple can be suppressed, and the differential characteristics can be further improved.

Furthermore, in the single-phase differential conversion circuits 40 and 40_2, the change in the phase difference between the differential amplifiers is more sensitive to the transmission lines 31_2 and 32_1 connected to the output terminal of the differential amplifier 21 at the subsequent stage than to the transmission lines 31_1 and 32_2 connected to the output terminal of the differential amplifier 11.

Therefore, by making the lengths of the transmission lines 31_1 and 32_2 connected to the output terminals of the differential amplifiers at the preceding stage longer than the transmission lines 31_2 and 32_1 connected to the output terminals of the differential amplifiers at the subsequent stage, the sensitivity in the single-phase differential conversion circuit 40 can be reduced, and the influence of manufacturing variations can be reduced.

### Modification Example 1

The single-phase differential conversion circuit according to the present modification example includes a distribution amplifier designed with a distributed constant instead of the differential amplifier in the single-phase differential conversion circuits according to the first to fourth embodiments. Accordingly, the characteristics of the single-phase differential conversion circuit can be broadened.

The frequency ripple can be reduced by matching the characteristic impedance of the transmission line in the single-phase differential conversion circuit with the input/output impedance (typically 50 Ω) of the distribution amplifier.

### Fifth Embodiment

A single-phase differential conversion circuit according to a fifth embodiment of the present invention includes a compensation circuit 51 instead of the transmission line in the single-phase differential conversion circuits according to the first to fourth embodiments.

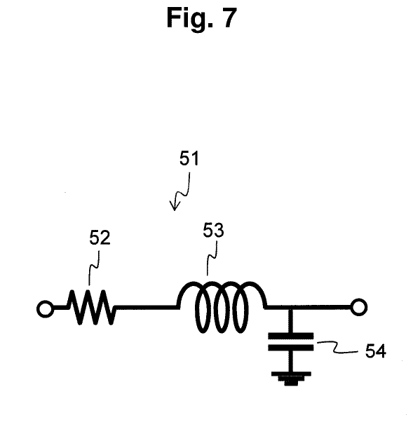

The compensation circuit 51 includes a lumped parameter element, and includes, for example, a resistor 52, an inductor 53, and a capacitor 54 as illustrated in FIG. 7. For example, in the compensation circuit 51, the resistor 52 and the inductor 53 are connected in series and the capacitor 54 is connected in parallel to the output terminal of the positive-phase circuit of the differential amplifier of the single-phase differential conversion circuit.

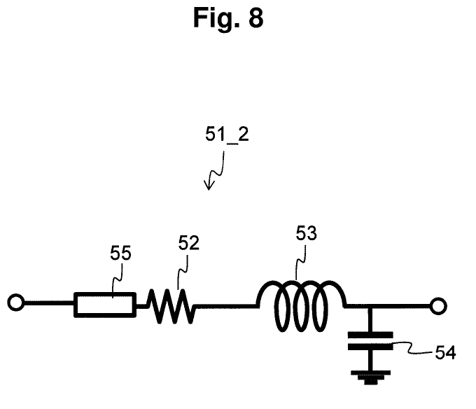

Alternatively, as illustrated in FIG. 8, a transmission line 55, the resistor 52, and the inductor 53 may be connected in series, and the capacitor 54 may be connected in parallel. The transmission line 55 may be shorter than the transmission lines used in the first to fourth embodiments.

As a result, the differential characteristics can be improved, the area of the single-phase differential conversion circuit can be reduced, and the degree of freedom in design can be improved.

### Sixth Embodiment

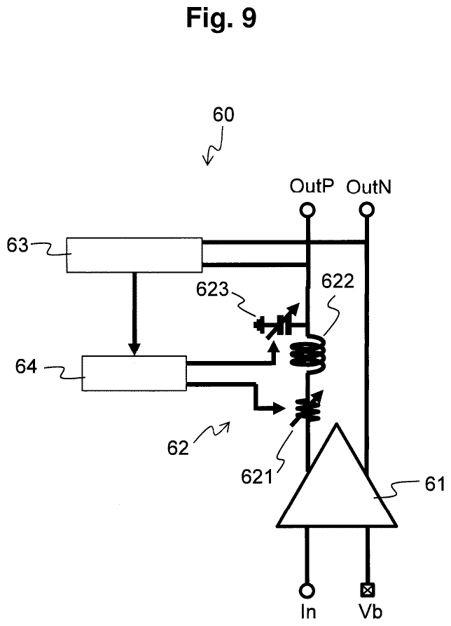

A single-phase differential conversion circuit according to a sixth embodiment of the present invention will be described with reference to FIG. 9.

As illustrated in FIG. 9, a single-phase differential conversion circuit 60 according to the present embodiment includes a differential amplifier 61, a compensation circuit 62, a detection circuit 63, and a control circuit 64.

The compensation circuit 62 is connected to an output terminal of a positive-phase circuit of the differential amplifier 61, a variable resistor 621 and an inductor 622 are connected in series, and a variable capacitor 623 is connected in parallel.

The detection circuit 63 is connected to output terminals OutP and OutN of the single-phase differential conversion circuit, and detects the intensity difference and the phase difference between differential signals of the positive-phase signal and the negative-phase signal.

The control circuit 64 is connected at an output to the variable resistor 621 and the variable capacitor 623 of the compensation circuit 62, and generates a control voltage of the variable resistor 621 so that the intensity difference between differential signals input from the detection circuit 63 is reduced.

The control circuit 64 generates a control voltage of the variable capacitor 623 so that the phase difference between the differential signals input from the detection circuit 63 becomes a predetermined value or less. The predetermined value may be, for example, about 10% of 180 degrees.

The control circuit 64 applies these control voltages to the variable resistor 621 and the variable capacitor 623.

According to the single-phase differential conversion circuit according to the present embodiment, the differential characteristics can be automatically controlled by detecting the intensity difference and the phase difference between the differential signals generated in the differential amplifier and performing feedback control. Therefore, the mismatch of the phase difference and the mismatch of the intensity difference can be reduced, and the differential characteristics can be improved.

Instead of the differential amplifier in the single-phase differential conversion circuit according to the fifth and sixth embodiments, a distribution amplifier designed with a distributed constant may be provided.

The embodiment of the present invention shows an example of a structure, dimensions and materials of each component in the configuration and manufacturing method of the single-phase differential conversion circuit. However, the present invention is not limited thereto. The single-phase differential conversion circuit is only required to exhibit its function and achieve effects.

### INDUSTRIAL APPLICABILITY

Embodiments of the present invention relate to a single-phase differential conversion circuit, and can be applied to a high-speed optical communication system.

### REFERENCE SIGNS LIST

10 SINGLE-PHASE DIFFERENTIAL CONVERSION CIRCUIT
11 Differential amplifier
111 Positive-phase circuit
111_1 Input terminal of positive-phase circuit
111_2 Output terminal of positive-phase circuit
112 Negative-phase circuit
12 Transmission line

1.-9. (canceled)

10. A single-phase differential conversion circuit, comprising:
a pair of input terminals and a pair of output terminals and configured to output a positive-phase signal and a negative-phase signal corresponding to an input signal input into one of the pair of input terminals;
a first differential amplifier including a positive-phase circuit configured to processing a positive-phase signal and a negative-phase circuit configured to process a negative-phase signal; and
a first transmission line having a first end connected to an output terminal of the positive-phase circuit of the first differential amplifier,
wherein the first transmission line is configured to rotate a phase of the positive-phase signal and reduce an intensity of the positive-phase signal.

11. The single-phase differential conversion circuit according to claim 10, further comprising:
a second differential amplifier including a positive-phase circuit configured to process a positive-phase signal and a negative-phase circuit configured to process a negative-phase signal, the second differential amplifier arranged in a subsequent stage of the first differential amplifier,
wherein an input terminal of the positive-phase circuit of the second differential amplifier is connected to a second end of the first transmission line, and
wherein an input terminal of the negative-phase circuit of the second differential amplifier is connected to an output terminal of the negative-phase circuit of the first differential amplifier.

12. The single-phase differential conversion circuit according to claim 11 further comprising a second transmission line connected to an output terminal of one of the positive-phase circuit and the negative-phase circuit of the second differential amplifier.

13. The single-phase differential conversion circuit according to claim 11, wherein each of the first differential amplifier and the second differential amplifier is a distribution amplifier.

14. The single-phase differential conversion circuit according to claim 11, wherein the first differential amplifier includes a tail current source.

15. The single-phase differential conversion circuit according to claim 10, further comprising:
a second differential amplifier including a positive-phase circuit configured to process a positive-phase signal and a negative-phase circuit configured to process a negative-phase signal, the second differential amplifier arranged in a preceding stage of the first differential amplifier, and
a second transmission line having a first end connected to an output terminal of the negative-phase circuit of the second differential amplifier,
wherein an output terminal of the positive-phase circuit of the second differential amplifier is connected to an input terminal of the positive-phase circuit of the first differential amplifier, and
wherein a second end of the second transmission line is connected to an input terminal of the negative-phase circuit of the first differential amplifier.

16. The single-phase differential conversion circuit according to claim 15, wherein each of the first differential amplifier and the second differential amplifier is a distribution amplifier.

17. The single-phase differential conversion circuit according to claim 15, wherein the first differential amplifier includes a tail current source.

18. The single-phase differential conversion circuit according to claim 10, wherein the first differential amplifier is a distribution amplifier.

19. The single-phase differential conversion circuit according to claim 10, wherein the first differential amplifier includes a tail current source.

20. The single-phase differential conversion circuit according claim 10, wherein
an input terminal of the positive-phase circuit and an input terminal of the negative-phase circuit of the first differential amplifier are connected to the respective one of the pair of input terminals, and
a second end of the first transmission line and an output terminal of the negative-phase circuit of the first differential amplifier are connected to the respective one of the pair of output terminals.

21. A single-phase differential conversion circuit, comprising:
a differential amplifier including a positive-phase circuit configured to process a positive-phase signal and a negative-phase circuit configured to process a negative-phase signal; and
a compensation circuit,
wherein the compensation circuit includes, at an output terminal of the positive-phase circuit, a resistor, an inductor, and a capacitor,
wherein the resistor is connected in series with the inductor, and
wherein the capacitor is connected in parallel with the resistor and the inductor.

22. The single-phase differential conversion circuit according to claim 21, wherein the compensation circuit further includes a transmission line connected in series with the resistor and the inductor.

23. The single-phase differential conversion circuit according to claim 22, further comprising:
a detection circuit connected to a terminal on a side of the positive-phase circuit and a terminal on a side of the negative-phase circuit; and
a control circuit connected to an output of the detection circuit,
wherein the resistor is a variable resistor,
wherein the capacitor has a variable capacitance,
wherein the detection circuit is configured to detect an intensity difference and a phase difference between the positive-phase signal and the negative-phase signal, and
wherein the control circuit is configured to control resistance of the resistor such that the intensity difference is reduced, and control capacitance of the capacitor such that the phase difference is equal to or less than a predetermined value.

24. The single-phase differential conversion circuit according to claim 21, wherein the differential amplifier is a distribution amplifier.

25. The single-phase differential conversion circuit according to claim 21, wherein the differential amplifier includes a tail current source.

26. The single-phase differential conversion circuit according to claim 21, further comprising:
a detection circuit connected to a terminal on a side of the positive-phase circuit and a terminal on a side of the negative-phase circuit; and
a control circuit connected to an output of the detection circuit,
wherein the resistor is a variable resistor,
wherein the capacitor has a variable capacitance,
wherein the detection circuit is configured to detect an intensity difference and a phase difference between the positive-phase signal and the negative-phase signal, and, and
wherein the control circuit is configured to control resistance of the resistor such that the intensity difference is reduced, and control capacitance of the capacitor such that the phase difference is equal to or less than a predetermined value.
